(19) United States
(12) Patent Application Publication
(10) Pub. No.: US 2024/0413268 A1
(43) Pub. Date: Dec. 12, 2024

(54) SEMICONDUCTOR DEVICE

(71) Applicant: EPISTAR CORPORATION, Hsinchu (TW)

(72) Inventors: Yi-Yang CHIU, Hsinchu (TW); Chun-Yu LIN, Hsinchu (TW); Chun Wei CHANG, Hsinchu (TW); Yi-Ming CHEN, Hsinchu (TW); Chen OU, Hsinchu (TW); Hung-Yu CHOU, Hsinchu (TW); Liang-Yi WU, Hsinchu (TW); Hsiao-Chi YANG, Hsinchu (TW)

(21) Appl. No.: 18/737,448

(22) Filed: Jun. 7, 2024

(30) Foreign Application Priority Data
Jun. 9, 2023 (TW) 112121608
Apr. 12, 2024 (TW) 113113824

(51) Int. Cl. H01L 33/40; H01L 33/22; H01L 33/38; H01L 33/44

(52) U.S. Cl. CPC H01L 33/405; H01L 33/22; H01L 33/387; H01L 33/44

(57) ABSTRACT

A semiconductor device includes a semiconductor stack, a reflective structure, and a conductive structure. The semiconductor stack includes a first semiconductor structure, a second semiconductor structure and an active region located between the first semiconductor structure and the second semiconductor structure. The reflective structure is located at a side of semiconductor stack closed to the first semiconductor structure, and includes a first metal. The conductive structure locates between the reflective structure and the first semiconductor structure, and includes a first region overlapping with the active structure and a second region which does not overlap with the active structure. The first metal in the second region has a concentration smaller than 5 atomic percent.

### CROSS REFERENCE TO RELATED APPLICATION

This application claims the right of priority based on TW Application Serial No. 112121608, filed on Jun. 9, 2023, and TW Application Serial No. 113113824, filed on Apr. 12, 2024, and the contents of which are hereby incorporated by reference in their entireties.

### TECHNICAL FIELD

The present disclosure relates to a semiconductor device, and particularly to a semiconductor device with a barrier structure.

### DESCRIPTION OF BACKGROUND ART

Semiconductor devices can be applied to a wide range of applications. Research and development of related materials have been continuously carried out. For example, a group III-V semiconductor material including a group III element and a group V element may be applied to various optoelectronic semiconductor devices, such as light-emitting diodes (LEDs), laser diodes (LDs), photodetectors (PDs), solar cells or power devices (such as switches or rectifiers). These optoelectronic semiconductor devices can be applied in various fields, such as illumination, medical care, display, communication, sensing, or power supply system. For example, in optoelectronic semiconductor devices, LEDs are widely used because of advantages of low energy consumption, rapid response, small volume and long operating lifetime, and lower power consumption, smaller chip size and better photoelectric conversion efficiency have always been the focus of industry research and development.

### SUMMARY OF THE DISCLOSURE

The present disclosure provides a semiconductor device. The semiconductor includes a semiconductor stack, a reflective structure, and a conductive structure. The semiconductor stack includes a first semiconductor structure, a second semiconductor structure and an active region located between the first semiconductor structure and the second semiconductor structure. The reflective structure is located at a side of semiconductor stack closed to the first semiconductor structure, and includes a first metal. The conductive structure locates between the reflective structure and the first semiconductor structure, and includes a first region overlapping with the active structure and a second region which does not overlap with the active structure. The first metal in the second region has a concentration smaller than 5 atomic percent.

### BRIEF DESCRIPTION OF THE DRAWINGS

The foregoing aspects and many of the attendant advantages of the present disclosure will become more readily appreciated as the same becomes better understood by reference to the following detailed description, when taken in conjunction with the accompanying drawings, wherein:

FIG. 1 is a top perspective view of a semiconductor device according to one embodiment of the present disclosure;

FIG. 2A is a schematic sectional view of the semiconductor device along a section line A-A′ in FIG. 1;

FIG. 2B is schematic sectional view of a semiconductor device according to one embodiment of the present disclosure;

FIG. 2C is a schematic sectional view of a semiconductor device according to one embodiment of the present disclosure;

FIG. 2D is a schematic sectional view of a semiconductor device according to one embodiment of the present disclosure;

FIG. 2E shows an enlarged sectional view of a region L in FIG. 2D;

FIG. 2F is a schematic sectional view of a semiconductor device according to one embodiment of the present disclosure;

FIG. 3 is a graph showing concentration distribution of a first metal along a line C-C′ in FIG. 2A;

FIG. 4 is a schematic sectional view of a semiconductor device according to one embodiment of the present disclosure;

FIG. 5 is a schematic sectional view of a light-detecting module according to one embodiment of the present disclosure;

FIG. 6 is a schematic sectional view of a semiconductor device according to one embodiment of the present disclosure;

FIG. 7 is a schematic sectional view of a semiconductor device according to one embodiment of the present disclosure; and

FIG. 8 is a schematic sectional view of a semiconductor package structure according to one embodiment of the present disclosure.

### DETAILED DESCRIPTION OF PREFERRED EMBODIMENTS

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

A person skilled in the art can realize that addition of other components based on a structure recited in the following embodiments is allowable. For example, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not physically contact each other. In addition, it should be realized that a positional relationship of a layer/structure may be altered when being observed in different orientations.

In addition, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

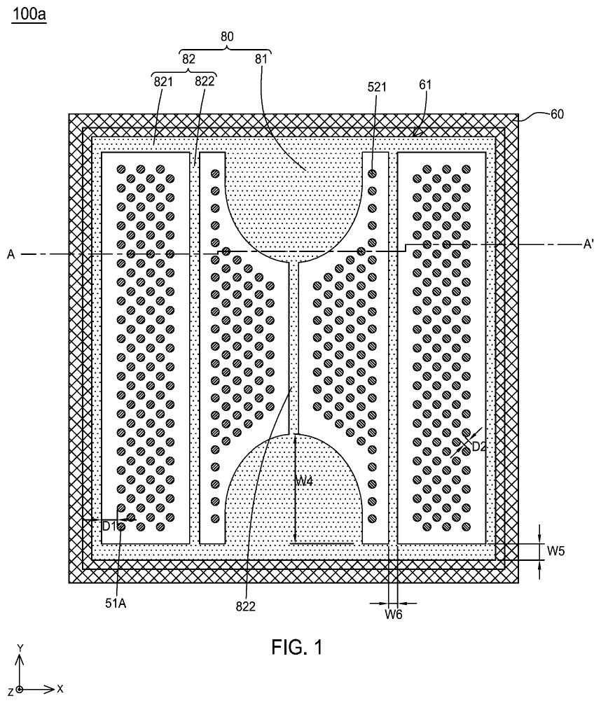

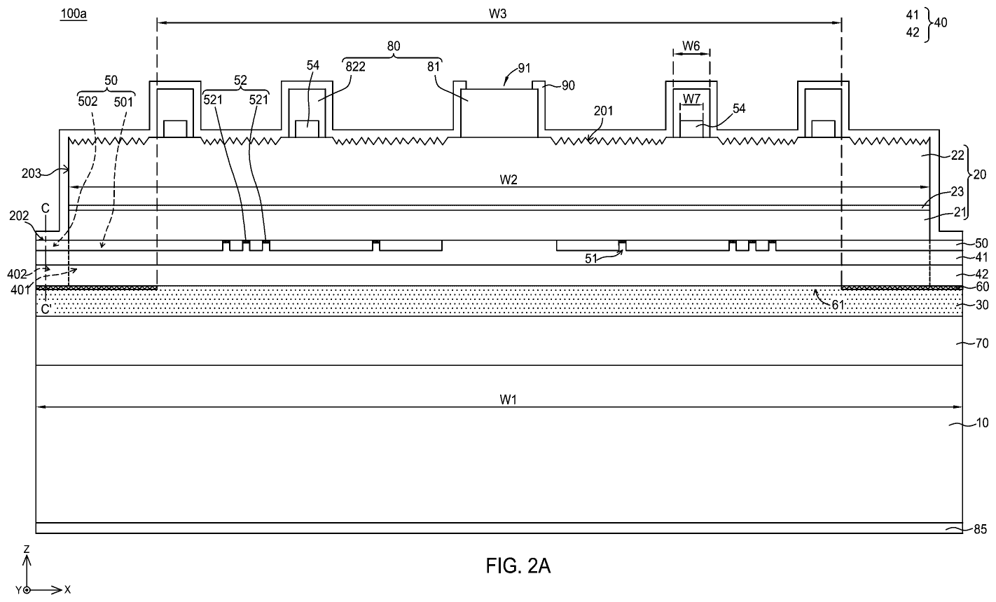

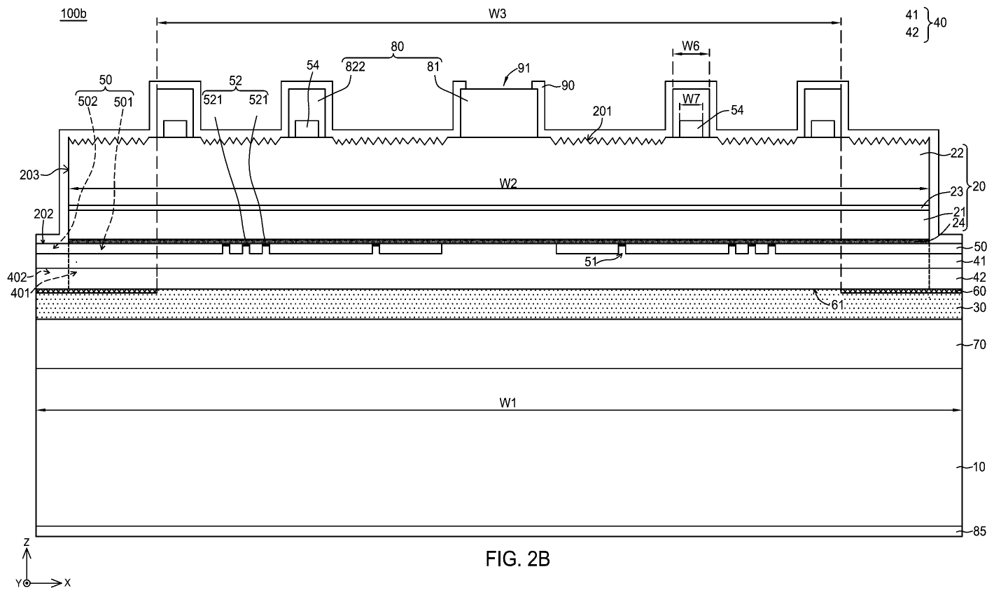

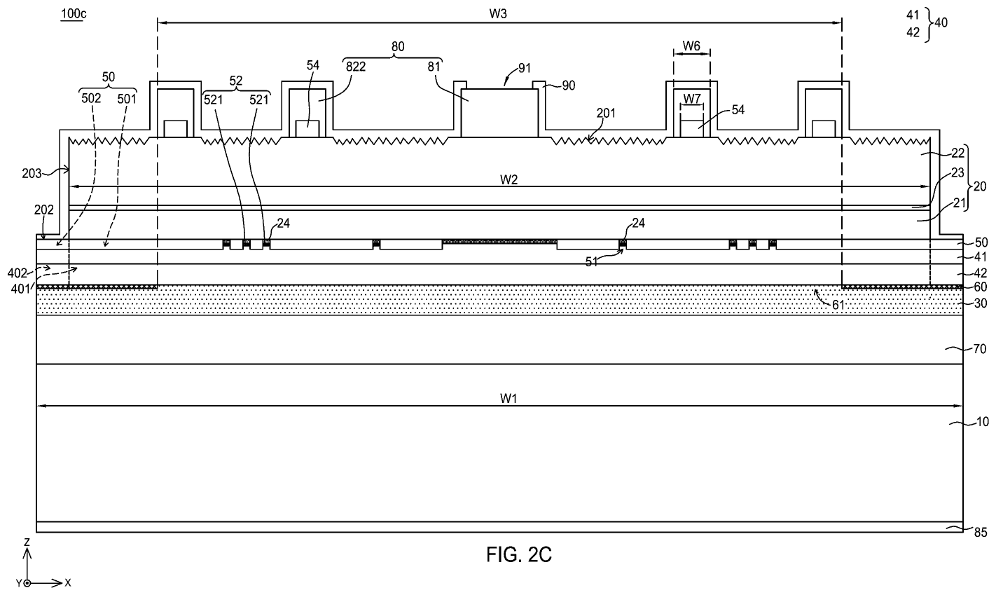

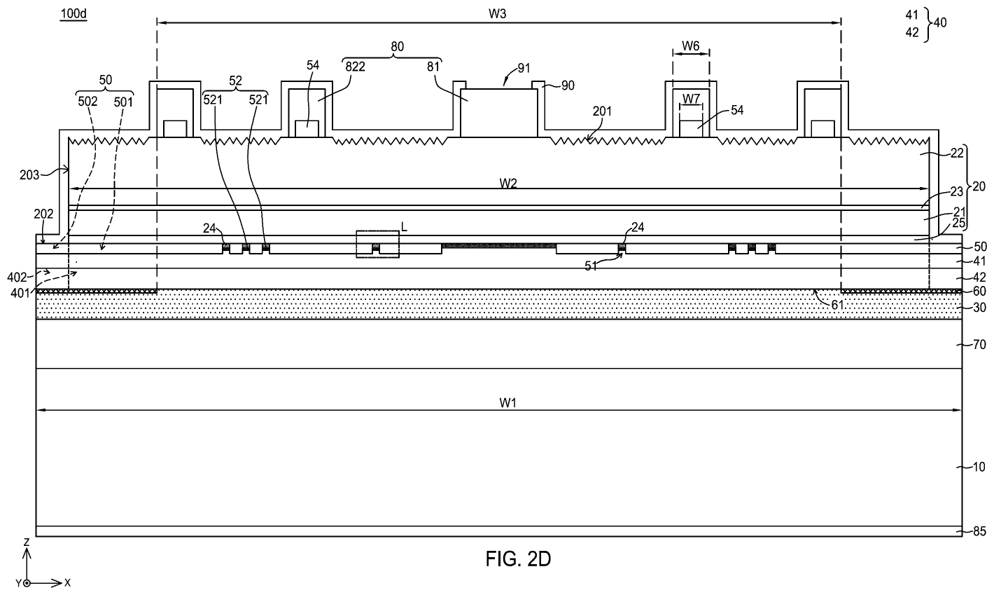

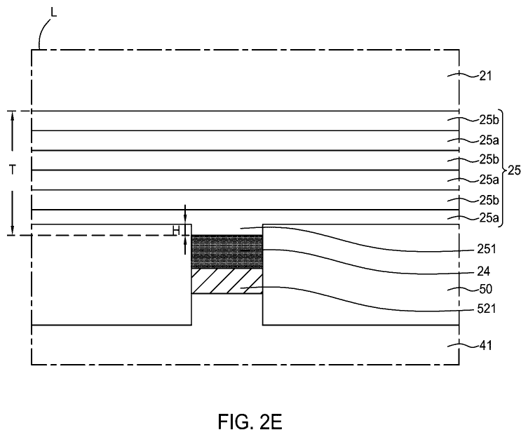

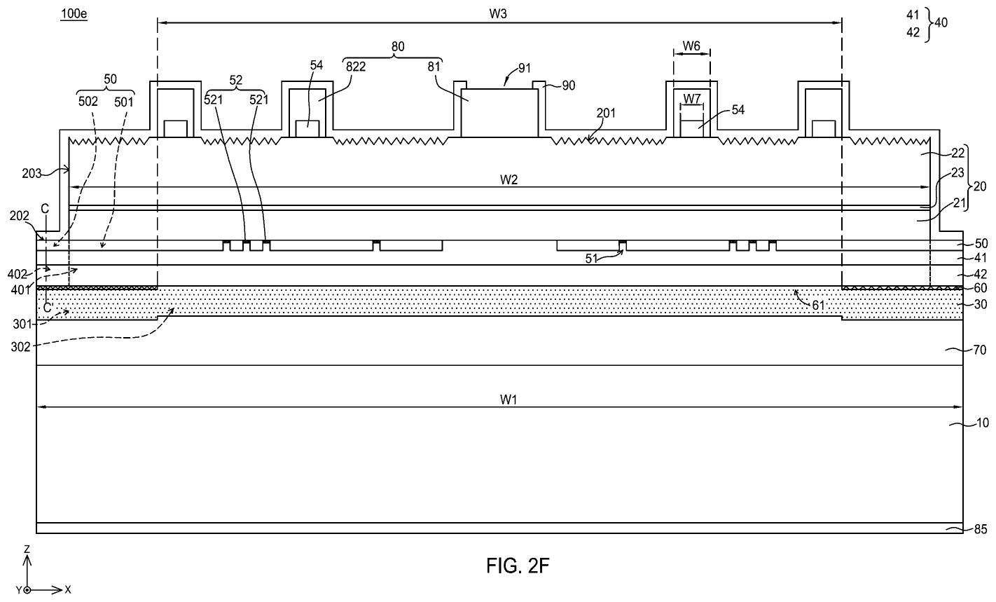

FIG. 1A is a schematic top perspective view of the semiconductor device 100a according to one embodiment of the present disclosure. FIG. 2A is a schematic sectional view along a section line A-A′ in FIG. 1A. As shown in FIG. 1, in this embodiment, the semiconductor device 100a has a shape of rectangle, which has two sides extending along X-axis and parallel to each other, and two sides extending along Y-axis and parallel to each other. In other embodiments, the shape of the semiconductor device 100a can also be a circle, polygon or irregular shape according to application requirements.

As shown in FIG. 2A, the semiconductor device 100a includes a semiconductor stack 20, a reflective structure 30 located below the semiconductor stack 20, and a conductive structure 40 located between the semiconductor stack 20 and the reflective structure 30. Further, the semiconductor device 100a may optionally include a base 10, an insulating structure 50, a barrier structure 60, a first contact structure 52, a bonding structure 70, a first electrode structure 80 and a second electrode structure 85.

The base 10 is disposed below the semiconductor stack 20 and provides the mechanical strength for supporting the semiconductor device 100a. In this embodiment, the base 10 is a support substrate that supports the semiconductor stack 20, and the base 10 and the reflective structure 30 are bonded together through the bonding structure 70. In one embodiment, the base 10 may be a growth substrate for growing the semiconductor stack 20.

The semiconductor stack 20 includes a first semiconductor structure 21, a second semiconductor structure 22 and an active region located between the first semiconductor structure 21 and the second semiconductor structure 22. The first semiconductor structure 21 is located between the base 10 and the second semiconductor structure 22. The semiconductor stack 20 may include a single heterostructure, a double heterostructure (DH), a double-side double heterostructure (DDH). The active region 23 may include a multiple quantum well (MQW) structure. The first semiconductor structure 21 and the second semiconductor structure 22 may have different conductivity types. For example, the first semiconductor structure 21 is n-type semiconductor and the second semiconductor structure 22 is p-type semiconductor, or the first semiconductor structure 21 is p-type semiconductor and the second semiconductor structure 22 is n-type semiconductor. Thereby, the first semiconductor structure 21 and the second semiconductor structure 22 can respectively provide electrons and holes, or holes and electrons. The p-type semiconductor may be a semiconductor doped with carbon (C), zinc (Zn), beryllium (Be) or magnesium (Mg). The n-type semiconductor may be a semiconductor doped with silicon (Si), germanium (Ge), tin (Sn), selenium (Se) or tellurium (Te). In one embodiment, the first semiconductor structure 21 and the second semiconductor structure 22 may have a doping concentration in a range of 5×1016/cm3 to 1×1020/cm3.

In one embodiment, the first semiconductor structure 21 and the second semiconductor structure 22 may respectively be a single layer or multiple layers, and may be a confinement layer and/or a cladding layer to limit the recombination of electron-hole pairs to occur in the active region 23. A power output by the semiconductor device 100a may be affected by a thickness of the first semiconductor structure 21 and/or a thickness the second semiconductor structure 22. In one embodiment, the thickness of the first semiconductor structure 21 may be in a range of 0.1 μm to 1.1 μm to improve the power of the semiconductor device 100a. In one embodiment, the thickness of the second semiconductor structure 22 may be in a range of 0.9 μm to 1.1 μm to improve the power of the semiconductor device 100a.

During operation of the semiconductor device 100a, the active region 23 emits a light with a peak wavelength. The light includes visible light and/or invisible light. The peak wavelength of the light is determined by the material composition of the active region 23. For example, when the material of the active region 23 includes InGaN, it may emit a blue light or a deep blue light with a peak wavelength of 400 nm to 490 nm, a green light with a peak wavelength of 490 nm to 550 nm or a red light with a peak wavelength of 560 nm to 650 nm; when the material of the active region 23 includes AlGaN, it may emit an ultraviolet light with a peak wavelength of 250 nm to 400 nm; when the material of the active region 23 includes InGaAs, InGaAsP, AlGaAs or AlGaInAs, it may emit an infrared light with a peak wavelength of 700 nm to 1700 nm; when the material of the active region 23 includes InGaP or AlGaInP, it may emit a red light with a peak wavelength of 610 nm to 700 nm, or a yellow light with a peak wavelength of 530 nm to 600 nm. The semiconductor stack 20 includes a light-emitting surface 201, and the light generated by the active region 23 is emitted outwards from the light-emitting surface 201. In this embodiment, the light-emitting surface 201 is a surface of the second semiconductor structure 22 away from the active region 23.

In one embodiment, when the active region 23 is the multiple quantum well structure, the active region 23 includes a plurality of barrier layers and a plurality of well layers that are alternately stacked with each other (not shown). The barrier layer has an energy gap larger than that of the well layer so that electrons and holes are confined in the well layer to improve the efficiency of light emission induced by electron-hole recombination. The barrier layer may include aluminum (Al), and an aluminum content of the barrier layer is proportional to the energy gap of the barrier layer. Specifically, the aluminum content is represented as a ratio of aluminum to all group III elements. For example, when the barrier layer include Alz1Ga(0.5-z1)In0.5P, z1 represents the aluminum content of the barrier layer. In one embodiment, the aluminum content of the barrier layer may be in the range of 0.15 to 0.35, such as 0.15, 0.2, 0.25, 0.3 or 0.35. According to application requirements, the aluminum content of the barrier layer can be adjusted to change characteristics of the semiconductor device 100a. For example, increasing the aluminum content of the barrier layer can improve the ability of confining electrons in the barrier layer to improve the efficiency of efficiency of light emission of the semiconductor device 100a. On the other hand, reducing the aluminum content of the barrier layer can reduce an operating voltage of the semiconductor device 100a. In one embodiment, the active region 23 may have 10 to 30 pairs of the barrier layer and well layer, such as 10 pairs, 12 pairs, 15 pairs, 18 pairs, 20 pairs, 25 pairs, or 30 pairs.

As shown in FIG. 2A, in a horizontal direction (along X-axis or Y-axis), the base 10 has a first width W1, and the active region 23 of the semiconductor stack 2 has a second width W2 smaller than the first width W1. Specifically, during manufacturing the semiconductor device 100a, a first etching process is performed on the semiconductor stack 20 to remove a portion of the second semiconductor structure 22, a portion of the active region 23 and a portion of the first semiconductor structure 21, so that a width of the active region 23 is reduced from the first width W1 to the second width W2. The first etching process may be wet etching or dry etching, such as inductively coupled plasma etching (ICP), reactive ion etching (RIE), or other etching technologies that can be used for semiconductor etching. Through the first etching process, an etching stop surface 202 and a sidewall 203 are formed. The sidewall 203 connects the light-emitting surface 201 and the etching stop surface 202. The insulating structure 50 may be an etching stop layer of the first etching process. In this embodiment, an upper surface of the insulating structure 50 is the etching stop surface 202, and the sidewall 203 is a sidewall of the semiconductor stack 20. The position of the etching stop surface 202 is controllable by adjusting parameters of the first etching process, and the etching stop surface 202 may be located between the light-emitting surface 201 and the insulating structure 50. For example, the etching stop surface 202 can be an exposed surface of the first semiconductor structure 21 located between the active region 23 and the insulating structure 50 (not shown).

Referring to FIG. 2A, the reflective structure 30 is located between the base 10 and the first semiconductor structure 21. The reflective structure 30 is conductive and reflects the light emitted from the active region 23 towards the second semiconductor structure 22. Thus, the light is directed to emits outwards through the light-emitting surface 201 and the efficiency of light emission of the semiconductor device 100a is enhanced. In one embodiment, the reflective structure 30 has a reflectivity of more than 80% for the light emitted from the active region 23. In one embodiment, the reflective structure 30 includes a first metal, such as silver (Ag), aluminum (Al), copper (Cu), tin (Sn) or indium (In).

As shown in FIG. 2A, the conductive structure 40 is located between the reflective structure 30 and the first semiconductor structure 21, and the insulating structure 50 is located between the conductive structure 40 and the first semiconductor structure 21. The insulating structure 50 can be a patterned structure and includes a plurality of first openings 51 that are separated from each other. The plurality of first openings 51 expose the first semiconductor structure 21, and the conductive structure 40 fills the plurality of first openings 51 for contacting and forming an electrical connection with the first semiconductor structure 21. The conductive structure 40 facilitate current spreading in the horizontal direction (along X-axis or Y-axis). Through the plurality of first openings 51 and the conductive structure 40, the current can evenly flow into or out of the first semiconductor structure 21 so the semiconductor device 100a can have better uniformity of light emission. In one embodiment, the conductive structure 40 and/or the insulating structure 50 may have a width substantially the same as the first width W1 of the base 10. In one embodiment, the conductive structure 40 and/or the insulating structure 50 is transparent to the light emitted by the active region 23. For example, the conductive structure 40 and/or the insulating structure 50 may have a transmittance of at least 80%. The conductive structure 40 may be a single layer or multiple layers. When the conductive structure 40 is multiple layers, each layer can have the same or different materials. In this embodiment, the conductive structure 40 includes a first conductive layer 41 and a second conductive layer 42. The first conductive layer 41 is located between the insulating structure 50 and the second conductive layer 42 and contacts the first semiconductor structure 21.

As shown in FIG. 2A, the conductive structure 40 includes a first region 401 that overlaps with the active region 23 in a vertical direction (along Z-axis), and a second region 402 that does not overlap with the active region 23 in the vertical direction. The insulating structure 50 includes a third region 501 that overlaps with the active region 23 in the vertical direction, and a fourth region 502 that does not overlap the active region 23 in the vertical direction. In other words, the second region 402 and the fourth region 502 correspond to the regions of the semiconductor stack 20 that are removed during the first etching process. A boundary between the first region 401 and the second region 402 and a boundary between the third region 501 and the fourth region 502 correspond to sidewall 203 of the semiconductor stack 20. That is to say, the boundary between the first region 401 and the second region 402 and the boundary between the third region 501 and the fourth region 502 are substantially aligned with the sidewall 203.

As shown in FIG. 2A, the barrier structure 60 is located between the reflective structure 30 and the insulating structure 50, and may be corresponding to the second region 402 and/or the fourth region 502. In one embodiment, the barrier structure 60 is disposed between the reflective structure 30 and the conductive structure 40. During manufacturing or operating the semiconductor device 100a, the first metal of the reflective structure 30 may diffuse into the conductive structure 40 and/or the insulating structure 50 due to temperature, electric field and/or pressure, and the first metal in the second region 402 and/or the fourth region 502 may form a potential conductive path to the etching stop surface 202. When operating the semiconductor device 100a, existence of the potential conductive path may cause charges accumulate at the etching stop surface 202 or the sidewall 203, and results in a risk of current leakage. By disposing the barrier structure 60 corresponding to the second region 402 and/or the fourth region 502, the first metal is blocked by the barrier structure 60 and is difficult to diffuse into the second region 402 and the fourth region 502. In other words, disposing the barrier structure 60 can keep the first metal in a low concentration within the second region 402 of the conductive structure 40 and/or the fourth region 502 of the insulating structure 50. In one embodiment, the concentration of the first metal in the second region 402 and/or the fourth region 502 is smaller than 5 atomic percent (at %) to prevent forming the potential conductive path and causing current leakage problems. The atomic percentage represents a ratio of a detected number of atoms of an individual element to a detected number of atoms of all detected elements. For example, assuming that the conductive structure 40 is indium zinc oxide (IZO) and an analysis of composition is performed at a certain range or a certain point in the second region 402. The detected number of the first metal is A; the detected number of indium is B; the detected number of oxygen is C; and the detected number of zinc atoms is D. Therefore, the atomic percentage of the first metal can be represented as (A/(A+B+C+D))*100%.

The barrier structure 60 may be a single layer or multiple layers. For example, the barrier structure 60 can include a first layer and a second layer (not shown). The first layer blocks the diffusion of the first metal and may reflect the light emitted by the active region 23. The second layer is located between the first layer and the conductive structure 40 to bond the first layer to the conductive structure 40. In one embodiment, the barrier structure 60 may have a thickness larger than or equal to 100 nm and smaller than or equal to 300 nm.

In one embodiment, the barrier structure 60 further includes a second opening 61. As shown in FIGS. 1 and 2A, the second opening 61 overlaps with the active region 23 in the vertical direction (along Z-axis), and the reflective structure 30 locates in the second opening 61 to directly contact the conductive structure 40. The second opening 61 has a third width W3 that is smaller than or equal to the second width W2 of the active region 23. In other words, a width of the barrier structure 60 is larger than or equal to the width of the second region 402 and/or the fourth region 502 to reduce the possibility of horizontal diffusion of the first metal. In one embodiment, a difference between the third width W3 and the second width W2 is between 0 μm and 30 μm.

Referring to FIG. 2A, the first contact structure 52 is disposed between the insulating structure 50 and the semiconductor stack 20, and directly contacts the first semiconductor structure 21. Specifically, in this embodiment, the first contact structure 52 includes a plurality of first contact portions 521 that are separated from each other. The first contact structure 52 and the insulation structure 50 may be staggered in the horizontal direction. That is. the plurality of first contact portions 521 may correspond to the plurality of first openings 51 of the insulation structure 50. In this embodiment, the first contact portion 521 is located in the first opening 51, and the first conductive layer 41 fills the first opening 51 and contacts the first contact portion 521 to form an electrical connection therebetween. The first contact structure 52 may reduce a resistance between the first semiconductor structure 21 and the conductive structure 40, thereby lowering the operating voltage of the semiconductor device 100a.

The first contact structure 52 may include a semiconductor and has a conductivity type the same as that of the first semiconductor structure 21. The first contact structure 52 has a doping concentration higher than that of the first semiconductor structure 21. For example, the doping concentration of the first contact structure 52 can be between 1×1018/cm3 and 1×1020/cm3. The first contact structure 52 may be a single layer or multiple layers, and when it is multiple layers, the materials of each layer may be the same or different. In the vertical direction, the first contact structure 52 may have a thickness smaller than, equal to, or larger than that of the insulation structure 50. In one embodiment that the thickness of the first contact structure 52 is larger than or equal to the thickness of the insulation structure 50 (not shown), the first contact portion 521 occupy the first opening 51 and the first conductive layer 41 does not fill the first opening 51. In one embodiment, the thickness of the first contact structure 52 is between 50 nm and 100 nm. In one embodiment, the thickness of the insulating structure 50 is between 20 nm and 180 nm.

Referring to FIG. 2A, the first electrode structure 80 is disposed on the second semiconductor structure 22 and forms an electrical connection with the second semiconductor structure 22. The second electrode structure 85 is disposed below the base 10 and forms an electrical connection with the first semiconductor structure 21. Thus, the semiconductor device 100a forms a light-emitting device with a vertical structure, and the semiconductor device 100a can be operated by connecting the first electrode structure 80 and the second electrode structure 85 to an external power source. In this embodiment, the first electrode structure 80 is disposed on the light-emitting surface 201 and includes an electrode pad 81 and an extension portion 82. The extension portion 82 has a first segment 821 extending from the electrode pad 81 and a second segment 822 connecting the first segment 821. Referring to FIG. 1, in this embodiment, the first electrode structure 80 includes two electrode pads 81, a plurality of first segments 821 and a plurality of second segments 822. The two electrode pads 81 are respectively disposed on two opposite sides of the semiconductor device 100a that are parallel to X-axis. The plurality of first segments 821 connect the electrode pads 81 and extend along X-axis. The plurality of second segments 822 extend along Y-axis, and connect the plurality of first segments 821 or the two electrode pads 81. The plurality of second segments 822 are separated from each other. In one embodiment, the plurality of first openings 51 of the insulating structure 50 does not overlap with the first electrode structure 80 in the vertical direction. In other words, when being viewed from top, the plurality of first openings 51 does not overlap with the electrode pads 81, the plurality of first segments 821 and the plurality of second segments 822. As such, the first electrode structure 80 can be prevented from blocking the light emitted by the active region 23, and the efficiency of light emission of the semiconductor device 100a is improved.

As shown in FIG. 1, when being viewed from top, there is a first distance D1 between a first opening 51A and the electrode pad 81 or between the first opening 51A and the extension portion 82, in which the first opening 51A is the closest first opening 51 to the electrode pad 81 and/or the extension portion 82. In one embodiment, the first distance D1 may be in a range of 5 μm to 50 μm. The plurality of first openings 51 can be arranged in an array to improve current spreading effect in the semiconductor stack 20 and uniformity of light emission. In one embodiment, there is a second distance D2 between any two adjacent first openings 51, and the second distance D2 may be between 3 μm and 10 μm. In one embodiment, a roughened structure may be optionally formed on a part of the light-emitting surface 201 which is not covered by the first electrode structure 80 to increase light extraction.

In the horizontal direction, the electrode pad 81 has a fourth width W4 (along Y-axis), the first segment 821 has a fifth width W5 (along Y-axis), and the second segment 822 has a sixth width W6 (along X-axis). In one embodiment, the fifth width W5 is smaller than the fourth width W4, and the sixth width W6 is smaller than the fifth width W5. As such, the light blocking effect of the first electrode structure 80 can be further reduced.

In one embodiment, the first contact structure 52 does not dispose below the electrode pad 81 and does not overlap with the electrode pad 81. Thus, the resistance between the first semiconductor structure 21 and the conductive structure 40 below the electrode pad 81 is not reduced to avoid current crowding effect occurring below the electrode pad 81. In one embodiment, the insulating structure 50 may not be disposed below the electrode pad 81. In other words, the insulating structure 50 and the electrode pad 81 do not overlap in the vertical direction to improve reliability of the semiconductor device 100a.

As shown in FIG. 2A, the semiconductor device 100a may optionally include a second contact structure 54 disposed between the second semiconductor structure 22 and the first electrode structure 80. The second contact structure 54 may reduce the resistance between the first electrode structure 80 and the second semiconductor structure 22 to further reduce the operating voltage of the semiconductor device 100a. The second contact structure 54 includes a semiconductor material and has a conductivity type the same as that of the second semiconductor structure 22. In one embodiment, the second contact structure 54 may have a doping concentration higher than that of the second semiconductor structure 22. For example, the doping concentration of the second contact structure 54 may be between 1×1018/cm3 and 1×1020/cm3. The second contact structure 54 may be a single layer or multiple layers. When the second contact structure 54 is multiple layers (not shown), the material and/or the doping concentration of each layer can be the same or different. In one embodiment, the second contact structure 54 is only disposed below the second segment 822 to improve current spreading. In one embodiment, the second contact structure 54 has a seventh width W7, and the seventh width W7 is smaller than or equal to the sixth width W6 of the second segment 822.

The semiconductor device 100a may also optionally include a protecting layer 90 covering surfaces of the semiconductor stack 20 to prevent the semiconductor stack 20 from being affected by the environment. Specifically, the protecting layer 90 covers the first electrode structure 80, the light-emitting surface 201, the etching stop surface 202 and the sidewall 203 to prevent the semiconductor stack 20 from forming unwanted electric path. The protecting layer 90 also prevents the semiconductor stack 20 from interacting with the environment to improve reliability of the semiconductor device 100a. The protecting layer 90 may be transparent to the light emitted by the active region 23, such as having a transmittance of at least 80% for the light. The protecting layer 90 includes a third opening 91 corresponding to the electrode pad 81 for an external wire to connect the electrode pad 81. In one embodiment, the third opening 91 has a width smaller than the fourth width W4 of the electrode pad 81.

FIG. 2B is a schematic sectional view of a semiconductor device 100b according to one embodiment of the present disclosure. The semiconductor device 100b has a structure similar to the structure of the semiconductor device 100a. As shown in FIG. 2B, the semiconductor stack 20 of the semiconductor device 100b optionally include a current spreading layer 24 located at a side of the first semiconductor structure 21 away from the active region 23. The current spreading layer 24 can be a continuously layer formed below the first semiconductor structure 21 and contacts the insulating structure 50 and the first contact structure 52, and may facilitate current spreading effect along the horizontal direction (along X-axis and/or Y-axis) in the semiconductor stack 20 to improve the uniformity of light emission. In this embodiment, the first contact portion 521 is located in the first opening 51 and contacts the current spreading layer 24, and the first conductive layer 41 fills the first opening 51 to form the electrical connection with the first contact structure 52 and the current spreading layer 24. The current spreading layer 24 may have the same material (such as GaP) and the same conductivity type (such as p-type) as the first semiconductor structure 21. In one embodiment, the current spreading layer 24 has a doping concentration larger than or equal to that of the first semiconductor structure 21 so as to improve current spreading effect. The doping concentration of the current spreading layer 24 may be smaller than the doping concentration of the first contact structure 52. In one embodiment, a thickness of the current spreading layer 24 may be larger than or equal to 5 nm and smaller than or equal to 100 nm. In the embodiment of FIG. 2B, the aforementioned first etching process also removes a portion of the current spreading layer 24, and the upper surface of the insulating structure 50 is the etching stop surface 202. In one embodiment, the first etching process can be controlled to stop before reaching the insulating structure 50, so that the etching stop surface 202 is an exposed surface of the current spreading layer 24 located between the first semiconductor structure 21 and the insulating structure 50 (not shown).

The current spreading layer 24 may be a patterned layer. Referring to FIG. 2C for a schematic sectional view of a semiconductor device 100c according to one embodiment of the present disclosure. The semiconductor device 100c has a structure similar to the structure of the semiconductor device 100b. As shown in FIG. 2C, the current spreading layer 24 of the semiconductor device 100c may have a pattern corresponding to the plurality of first openings 51 of the insulating structure 50. Specifically, the current spreading layer 24 has a projected area when being projected on the active region 23. In this embodiment, the current spreading layer 24 of the semiconductor device 100c is not overlapped with the insulating structure 50 in the vertical direction, and the projected area thereof is reduced with respect to the current spreading layer 24 in the semiconductor device 100b. Thus, light absorption of the current spreading layer 24 can be reduced. In this embodiment, the first contact portion 521 and the current spreading layer 24 located in the first opening 51, and the first conductive layer 41 fills the first opening 51 to form the electrical connection with the first contact structure 52 and the current spreading layer 24. The first contact portion 521 reduce a resistance between the current spreading layer 24 and the first conductive layer 41.

The current spreading layer 24 may not reduce the resistance between the first semiconductor structure 21 and the first conductive layer 41. In the embodiments shown in FIGS. 2B and 2C, the current spreading layer 24 forms under the electrode pad 81, but the first contact structure 52 and the insulation structure 50 do not form under the electrode pad 81. Therefore, current crowding effect below the electrode pad 81 can be avoided.

FIG. 2D shows a schematic sectional view of a semiconductor device 100d according to one embodiment of the present disclosure, and FIG. 2E shows an enlarged sectional view of a region L in FIG. 2D. The semiconductor device 100d has a structure similar to the structure of the semiconductor device 100c. In this embodiment, the semiconductor device 100d optionally includes a third semiconductor structure 25 located between the first semiconductor structure 21 and the conductive structure 40, and may be disposed between the current spreading layer 24 and the first semiconductor structure 21. The third semiconductor structure 25 includes a semiconductor material and has a conductivity type the same as that of the first semiconductor structure 21. Referring to FIG. 2E, the third semiconductor structure 25 may include a protruding portion 251 formed at a side of the third semiconductor structure 25 away from the first semiconductor structure 21. The protruding portion 251 extends towards the conductive structure 40 and is located in the first opening 51. The position of the protruding portion 251 may correspond to the position of the first contact portion 521 and/or the first opening 51. Specifically, as shown in FIGS. 2D and 2E, the first contact structure 52 forms the plurality of first contact portions 521 through a second etching process. The current spreading layer 24 is patterned by the second etching process, and the protruding portion 251 is formed during the second etching process. The third semiconductor structure 25 can be an etching stop layer for the second etching process to prevent the first semiconductor structure 21 from being damaged to affect the reliability of the semiconductor device 100d. In one embodiment, the third semiconductor structure 25 can also enhance the effect of current spreading in the horizontal direction (along X-axis and/or Y-axis).

As shown in FIG. 2E, in the vertical direction, the third semiconductor structure 25 has a thickness T and the protruding portion 251 has a height H. In one embodiment, the thickness T of the third semiconductor structure 25 is larger than the thickness of the current spreading layer 24. In one embodiment, the thickness T of the third semiconductor structure 25 can be in a range of 100 nm to 200 nm. In one embodiment, the height H can be in a range of 0 nm to 50 nm. In one embodiment, a ratio of the height H to the thickness T may be between 0 and 0.5, such as 0, 0.1, 0.2, 0.3, 0.4 or 0.5.

The third semiconductor structure 25 may be a single layer or multiple layers. When the third semiconductor structure 25 is a single layer, it may include a quaternary compound semiconductor, such as a single layer of (Alx1Ga1-x1)1-y1Iny1P, wherein 0.6≤x1≤0.8 and 0.4≤y1≤0.6. In one embodiment, the third semiconductor structure 25 includes a third layer 25a and a fourth layer 25b. In the embodiment of FIG. 2E, the third semiconductor structure 25 includes a plurality of third layers 25a and a plurality of fourth layers 25b that are alternately stacked with each other, and the plurality of third layers 25a and the plurality of fourth layers 25b may form a superlattice. In one embodiment, the third semiconductor structure 25 may include 1 to 10 pairs of third layer 25a and fourth layer 25b.

The third layer 25a and the fourth layer 25b include a first group III element, and the third layer 25a and the fourth layer 25b have different atomic percentages of the first group III element. The first group III element may be aluminum (Al). The etching rate of the second etching process may be proportional to the atomic percentage of the first group III element. In one embodiment, the atomic percentage of the first group III element in the third layer 25a is smaller than that in the fourth layer 25b, so the etching rate of the third layer 25a is slower than the etching rate of the fourth layer 25b. Therefore, the third layer 25a is more suitable to be the etching stop layer for the second etching process. In one embodiment, the third layer 25a may be (Alx2Ga1-x2)1-y2Iny2P, and the fourth layer 25b may be (Alx3Ga1-x3)1-y3Iny3P, wherein 0.6x2≤0.8; 0.9≤x3≤1; and 0.4≤y2, y3≤0.6. The third layer 25a has a thickness larger than, equal to, or smaller than that of the fourth layer 25b. In one embodiment, each of the plurality of third layers 25a and/or each of the plurality of fourth layers 25b have the same thickness. In one embodiment, the thickness of the third layer 25a and/or the fourth layer 25b can be between 10 nm and 15 nm.

FIG. 2F shows a schematic sectional view of a semiconductor device 100c according to one embodiment of the present disclosure. The semiconductor device 100e has a structure similar to the structure of the semiconductor device 100a. In this embodiment, the reflective structure 30 may include a step structure formed at a side thereof away from the conductive structure 40. More specifically, the reflective structure 30 is conformally attached below the conductive structure 40 and the barrier structure 60, and includes a first part 301 that overlaps with the barrier structure 60 in the vertical direction and a second part 302 that does not overlap with the barrier structure 60 in the vertical direction. The first part 301 and the second part 302 may have the same thickness so that the step structure is formed at the side away from the conductive structure 40.

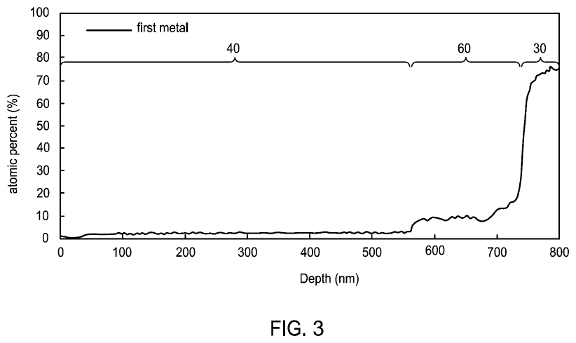

FIG. 3 is a graph showing the concentration distribution of the first metal along a line C-C′ of FIG. 2A. The analysis of the concentration of the first metal is conducted by suitable techniques such as an energy-dispersive X-ray spectroscopy (EDS), a wavelength dispersive spectrometers (WDS) or a secondary ion mass spectrometry (SIMS). In the embodiment of FIG. 3, the concentration of the first metal is analyzed by EDS. The depth of 0˜550 nm substantially corresponds to the conductive structure 40; the depth of 550 nm˜730 nm substantially corresponds to the barrier structure 60; and the depth 730 nm˜800 nm substantially corresponds to the reflective structure 30.

As shown in FIG. 3, the concentration of the first metal is the highest in the reflective structure 30, and drops apparently in the barrier structure 60, and remains below 5 atomic percent in the second region 402 of the conductive structure 40. It can be seen that the barrier structure 60 can effectively block the diffusion of the first metal and prevent the second region 402 of the conductive structure 40 and the fourth region 502 of the insulating structure 50 from forming potential conductive paths and causing current leakage. In one embodiment, the barrier structure 60 has a first side adjacent to the reflective structure 30 and a second side opposite to the first side. In other words, the second side is adjacent to the semiconductor stack 20. In one embodiment, the concentration of the first metal at the first side is larger than that at the second side. In one embodiment, the concentration of the first metal at the second side is larger than that in the second region 402 of the conductive structure 40.

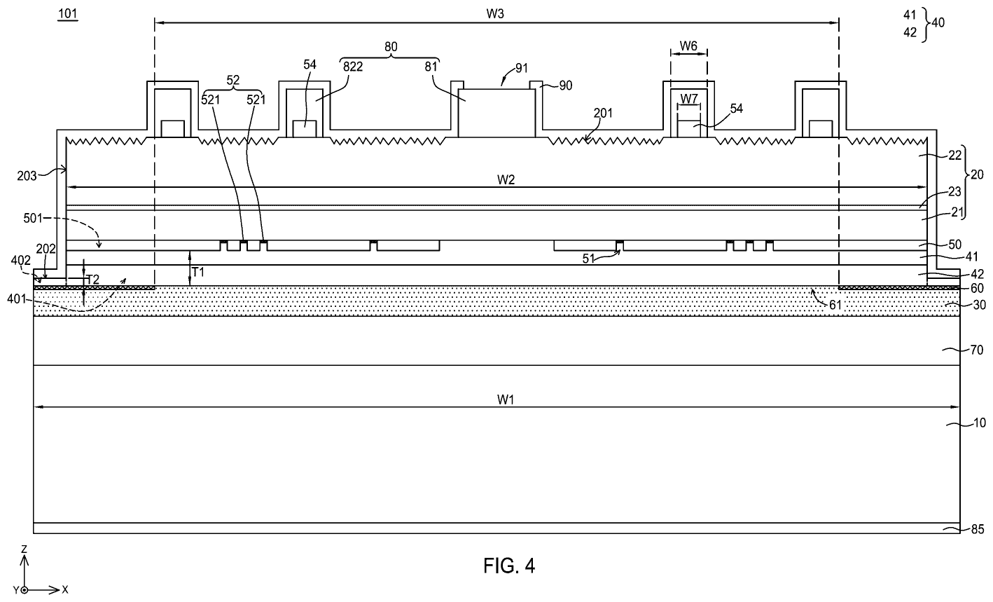

FIG. 4 is a schematic sectional view of a semiconductor device 101 according to one embodiment of the present disclosure. The semiconductor device 101 has a structure similar to the semiconductor device 100a. In this embodiment, the first etching process may continue to remove a portion of the insulating structure 50 and/or a portion of the conductive structure 40 after removing the first semiconductor structure 21 (or the current spreading layer 24). Specifically, in this embodiment, the fourth region 502 of the insulating structure 50 and a part of the second region 402 of the conductive structure 40 are removed by the first etching process, so that the etching stop surface 202 is formed at the conductive structure 40 and the sidewall 203 extends from the semiconductor stack 20 to the conductive structure 40. In this embodiment, the first region 401 of the conductive structure 40 includes the first conductive layer 41 and the second conductive layer 42, while the second region 402 only includes the second conductive layer 42. The first region 401 and the second region 402 of the conductive structure 40 respectively have a first thickness T1 and a second thickness T2. The first thickness T1 is a vertical distance from an interface between the conductive structure 40 and the insulating structure 50 to an interface between the conductive structure 40 and the reflective structure 30. The second thickness T2 is a vertical distance from an interface between the conductive structure 40 and the protecting layer 90 to the interface between the conductive structure 40 and the barrier structure 60. In this embodiment, the first thickness T1 is larger than the second thickness T2. The detailed descriptions of positions, relative relationships and material of other layers or structures as well as structural variations in this embodiment can be referred to the foregoing embodiments and are not repeatedly described herein.

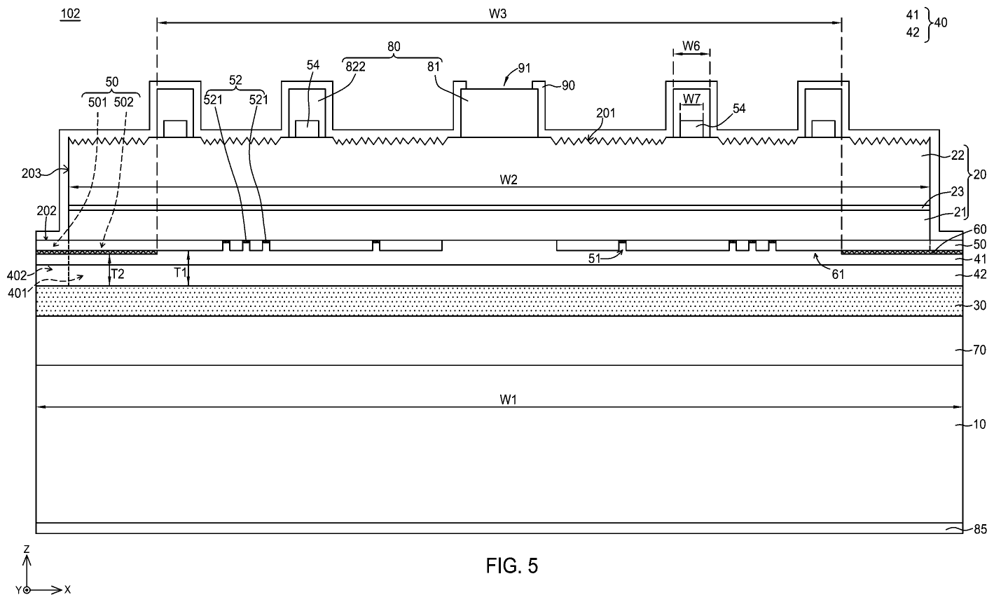

FIG. 5 is a schematic sectional view of a semiconductor device 102 according to one embodiment of the present disclosure. The semiconductor device 102 has a structure similar to the semiconductor device 100a. In this embodiment, the barrier structure 60 is disposed between the insulating structure 50 and the conductive structure 40, so that the second region 402 of the conductive structure 40 directly contacts the reflective structure 30 and is separated from the fourth region 502 of insulating structure 50 by the barrier structure 60. Therefore, the first metal is blocked by the barrier structure 60 and is difficult to diffuse into the fourth region 502, and the concentration of the first metal in the fourth region 502 is lower than 5 at % to prevent forming the potential conductive path in the fourth region 502 and causing leakage. In this embodiment, a concentration distribution of the first metal within the barrier structure 60 can be referred to the embodiment of FIG. 3.

In the embodiment of FIG. 5, the first thickness T1 of the first region 401 is the vertical distance from the interface between the conductive structure 40 and the insulating structure 50 to the interface between the conductive structure 40 and the reflective structure 30. Besides, the second thickness T2 of the second region 402 is a vertical distance from an interface between the conductive structure 40 and the barrier structure 60 to an interface between the conductive structure 40 and the reflective structure 30. In this embodiment, the first thickness T1 of the first region 401 is larger than the second thickness T2 of the second region 402. In one embodiment, an upper surface of the barrier structure 60 and an upper surface of the conductive structure 40 are substantially coplanar, and the sum of the second thickness T2 and the thickness of the barrier structure 60 is substantially equal to the first thickness T1. The detailed descriptions of positions, relative relationships and material of other layers or structures as well as structural variations in this embodiment can be referred to the foregoing embodiments and are not repeatedly described herein.

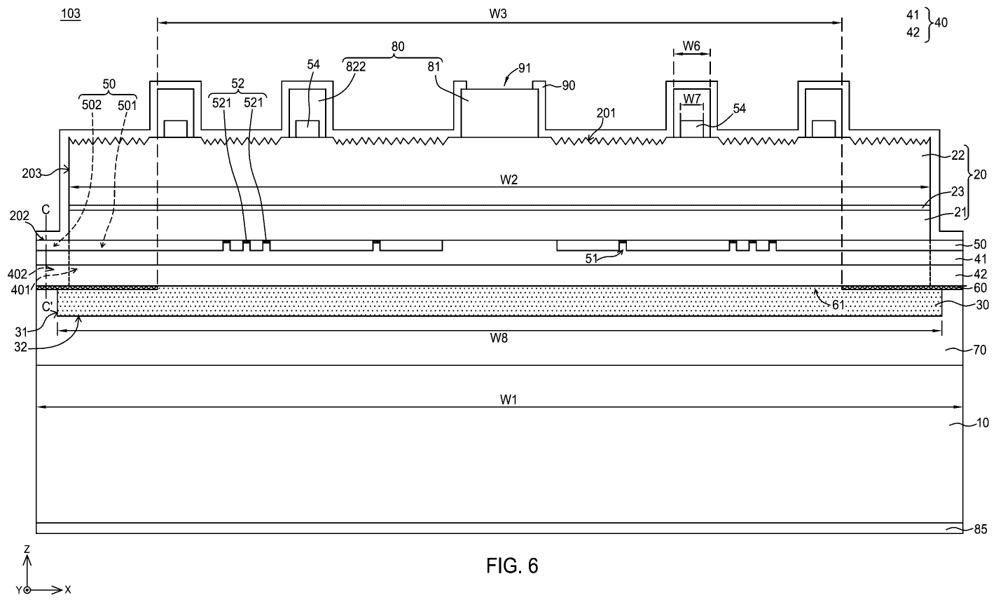

FIG. 6 is a schematic sectional view of a semiconductor device 103 according to one embodiment of the present disclosure. The semiconductor device 103 has a structure similar to the semiconductor device 100a. In this embodiment, the reflective structure 30 has an eighth width W8 in the horizontal direction (along X-axis and/or Y-axis), and the eighth width W8 is smaller than the first width W1 of the base 10 and larger than the third width W3 of the second opening 61. The eighth width W8 of the reflective structure 30 may be larger than, equal to, or smaller than the second width W2 of the active region 23. In one embodiment, when the eighth width W8 is larger than or smaller than the second width W2, a difference between the eighth width W8 and the second width W2 is larger than 0 μm and smaller than or equal to 10 μm. By reducing the width of the reflective structure 30, the overlapping area between the reflective structure 30 and the second region 402 and/or the fourth region 502 in the vertical direction becomes smaller, so the possibility of the first metal diffusing into the second region 402 and/or the fourth region 502 can further be reduced. Since the barrier structure 60 may reflect the light emitted by the active region 23, reducing the width of the reflective structure 30 does not affect the efficiency of light emission of the semiconductor device 103.

In one embodiment, in the vertical direction, a maximum thickness of the bonding structure 70 is larger than a maximum thickness of the reflective structure 30. The reflective structure 30 has a lower surface 32 away from the semiconductor stack 20 and a side surface 31 connecting the lower surface 32 and the barrier structure 60. The eighth width W8 is the width of the lower surface 32 in the horizontal direction. The bonding structure 70 contacts and covers the lower surface 32 and the side surface 31 of the reflective structure 30 and directly contacts the barrier structure 60. In one embodiment, the reflective structure 30 with the eighth width W8 may also include the step structure formed at a side thereof away from the conductive structure 40 (not shown). In one embodiment, the semiconductor device 103 may also include the current spreading layer 24 and the third semiconductor structure 25 mentioned in previous embodiments. The detailed descriptions of positions, relative relationships and material of other layers or structures as well as structural variations in this embodiment can be referred to the foregoing embodiments and are not repeatedly described herein.

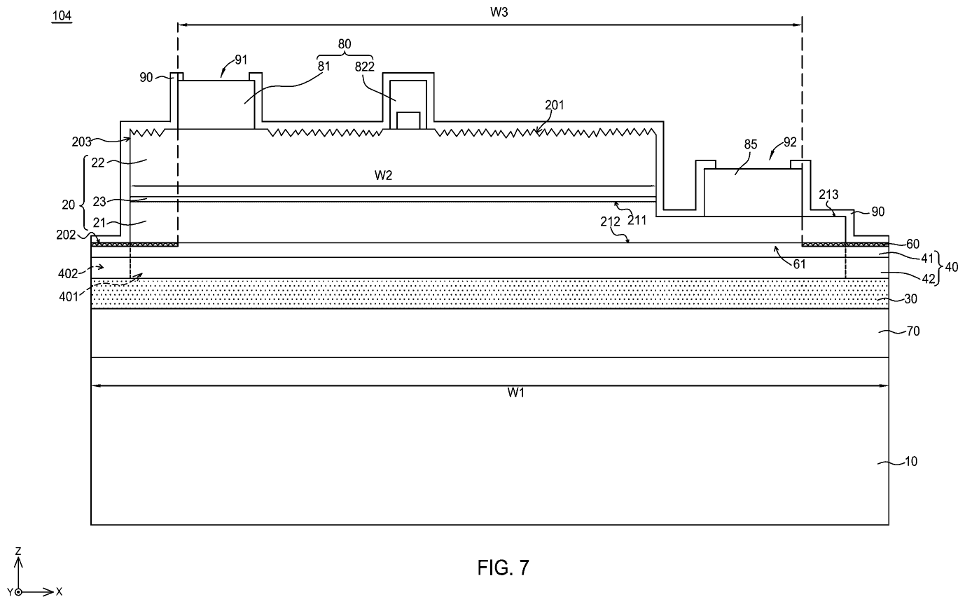

FIG. 7 is a schematic sectional view of a semiconductor device 104 according to one embodiment of the present disclosure. In this embodiment, the semiconductor device 104 does not have the insulating structure 50 described in previous embodiments. The first semiconductor structure 21 includes a first surface 211 facing the active region 23, a second surface 212 facing the base 10, and a third surface 213 located between the first surface 211 and the second surface 212. The third surface 213 is an exposed surface which is not covered by the active region 23 and the second semiconductor structure 22, and the second electrode structure 85 is disposed on the third surface 213 to electrically connect the first semiconductor structure 21. Thus, the semiconductor device 104 forms a light-emitting device with a horizontal structure. In this embodiment, the barrier structure 60 is disposed between the first semiconductor structure 21 and the conductive structure 40, and the upper surface of the barrier structure 60 may be the etching stop surface 202. In other words, the barrier structure 60 may be the etching stop layer of the aforementioned first etching process. As such, diffusion of the first metal can be blocked by the barrier structure 60, and charges transferred through the potential conductive path does not accumulate on the etching stop surface 202 or the sidewall 203. Therefore, current leakage problems can be avoided. In other embodiments, the barrier structure 60 can also be disposed between the reflective structure 30 and the conductive structure 40 (not shown), so that the first metal is difficult to diffuse into the second region 402 to form the potential conductive path.

As shown in FIG. 7, the protecting layer 90 covers the semiconductor stack 20, the first electrode structure 80 and the second electrode structure 85, and includes a fourth opening 92 corresponding to the second electrode structure 85 for connecting the external wire. In one embodiment, the first contact structure 52 (not shown) may be optionally disposed between the second electrode structure 85 and the first semiconductor structure 21 to reduce the operating voltage of the semiconductor device 104. In one embodiment, the first surface 211 of the first semiconductor structure 21 may have a width equal to the second width W2 of the active region 23, and the second surface 212 may have a width larger than the second width W2. The detailed descriptions of positions, relative relationships and material of other layers or structures as well as structural variations in this embodiment can be referred to the foregoing embodiments and are not repeatedly described herein.

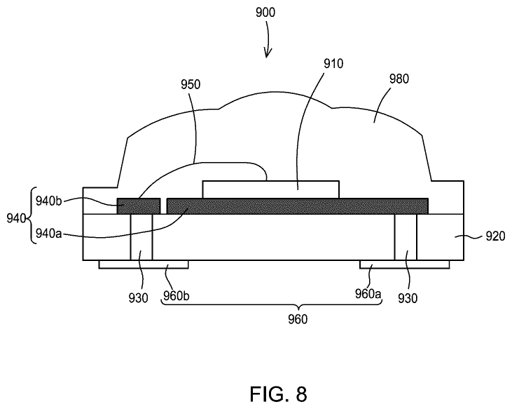

FIG. 8 shows a schematic sectional view of a semiconductor package structure 900 in accordance with one embodiment of the present disclosure. As shown in FIG. 8, the semiconductor package structure 900 includes a semiconductor device 910, a package substrate 920, a carrier 940, a bonding wire 950, a contact structure 960 and an encapsulating structure 980. The package substrate 920 includes a top surface and a bottom surface, and may include a ceramic or glass. The package substrate 920 has a plurality of through holes 930. Each through hole 930 may be filled with a conductive material such as metal for electrical conduction and/or heat dissipation. The carrier 940 may be located on the top surface of one side of the package substrate 920 and may include a conductive material such as metal. The contact structure 960 is located on the bottom surface of the package substrate 920. In the embodiment, the contact structure 960 includes a first contact pad 960a and a second contact pad 960b, and the first contact pad 960a and the second contact pad 960b can be electrically connected to the carrier 940 through the through holes 930. In an embodiment, the contact structure 960 may further include a thermal pad (not shown), for example, between the first contact pad 960a and the second contact pad 960b.

The semiconductor device 910 is located on the carrier 940 and may be the semiconductor device as described in any embodiment of the present disclosure (such as the semiconductor devices 100a, 100b, 100c, 100d, 100e, 101, 102, 103, 104 or variations thereof). In the embodiment, the carrier 940 includes a first portion 940a and a second portion 940b, and the semiconductor device 910 is electrically connected to the second portion 940b of the carrier 940 by the bonding wire 950. The material of the bonding wire 950 may include metal, such as gold (Au), silver (Ag), copper (Cu), or aluminum (Al), or may include alloy containing one or more of the above metals. The encapsulating structure 980 covers the semiconductor device 910 and protects the semiconductor device 910. Specifically, the encapsulating structure 980 may include a resin material, such as an epoxy resin, or a silicone resin. The encapsulating structure 980 may further include a plurality of wavelength conversion particles (not shown) to convert a first light emitted by the semiconductor device 910 into a second light. The wavelength of the second light is larger than the wavelength of the first light.

In some embodiment, the base 10 may include a conductive material or an insulating material. The conductive material may include gallium arsenide (GaAs), indium phosphide (InP), silicon carbide (SiC), gallium phosphide (GaP), zinc oxide (ZnO), gallium nitride (GaN), aluminum nitride (AlN), germanium (Ge) or silicon (Si). The insulating material may include sapphire, glass or quartz.

In some embodiment, the first semiconductor structure 21, the second semiconductor structure 22, the active region 23, the current spreading layer 24, the third semiconductor structure 25, the first contact structure 52 and the second contact structure 54 may respectively be the III-V semiconductor material. Specifically, the III-V semiconductor material can be a binary compound semiconductor (such as GaAs, GaP or GaN), a ternary compound semiconductor (such as InGaAs, AlGaAs, InGaP, AlInP, InGaN, AlGaN or AlAsSb) or a quaternary compound semiconductor (such as AlGaInAs, AlGaInP, AlInGaN, InGaAsP, InGaAsN or AlGaAsP).

In some embodiment, the reflective structure 30 is electrically conductive and includes a metal or an alloy. The metal may include copper (Cu), aluminum (Al), tin (Sn), gold (Au) or silver (Ag). The alloy may include at least two of the above metals.

In some embodiment, the conductive structure 40 may include a metal oxide. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), indium cerium oxide (ICO), indium tungsten oxide (IWO), indium titanium oxide (ITiO), indium zinc oxide (IZO), indium gallium oxide (IGO) or gallium aluminum zinc oxide (GAZO).

In some embodiment, the insulating structure 50 may include a dielectric material, such as silicon nitride (SiNx), aluminum oxide (AlOx), silicon oxide (SiOx), magnesium fluoride (MgFx), titanium oxide (TiOx), niobium pentoxide (Nb2O5) or combinations thereof. In some embodiment, the insulating structure 50 may include a distributed bragg reflector (DBR) structure. The DBR structure may include a plurality of first dielectric layers and a plurality of second dielectric layers that are alternately stacked with each other, and the first dielectric layers and the second dielectric layers have different refractive indices. For example, the DBR structure may be a combination of TiO2/Nb2O5, a combination of SiO2/Nb2O5 or a combination of SiO2/TiO2.

In some embodiment, the barrier structure 60 may include an oxide insulating material or a second metal that is different from the first metal of the reflective structure 30. The second metal may include nickel (Ni), gold (Au), titanium (Ti), tungsten (W) or platinum (Pt). The oxide insulating material may include aluminum oxide (Al2O3), silicon oxide (SiOx) or titanium oxide (TiOx).

In some embodiment, the bonding structure 70 may be electrically conductive and may include a metal oxide, a metal, or an alloy. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), indium titanium oxide (ITiO), indium zinc oxide (IZO), indium gallium oxide (IGO), gallium aluminum zinc oxide (GAZO) or a combination of the above metal oxides. The metal may include aluminum (Al), nickel (Ni), gold (Au), silver (Ag), titanium (Ti), tungsten (W), platinum (Pt), tin (Sn), indium (In) or copper (Cu). The alloy may include at least two of the above metals.

In some embodiment, the first electrode structure 80 and the second electrode structure 85 may respectively be a metal oxide, a metal or an alloy, and the first electrode structure 80 and the second electrode structure 85 may have the same or different materials. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). The metal may include germanium (Ge), beryllium (Be), zinc (Zn), titanium (Ti), aluminum (Al), nickel (Ni), gold (Au), platinum (Pt), tin (Sn) or copper (Cu). The alloy may include at least two of the above metals, such as such as GeAuNi, BeAu, GeAu or ZnAu.

In some embodiment, the protecting layer 90 may include an insulating material, such as tantalum oxide (TaOx), aluminum oxide (Al2O3), silicon oxide (SiOx), titanium oxide (TiOx), silicon nitride (SiNx), silicon oxynitride (SiOxNy), niobium pentoxide (Nb2O5) or spin-on glass (SOG).

The semiconductor device or the semiconductor package structure of the present disclosure can be applied to products in various fields, such as illumination, medical care, display, communication, sensing, or power supply system, for example, can be used in a light fixture, monitor, mobile phone, tablet, an automotive instrument panel, a television, computer, wearable device (such as watch, bracelet or necklace), traffic sign, outdoor display device, or medical device.

The embodiments of the present disclosure will be described in detail below with reference to the drawings. In the descriptions of the specification, specific details are provided for a full understanding of the present disclosure. The same or similar components in the drawings will be denoted by the same or similar symbols. It is noted that the drawings are for illustrative purposes only and do not represent the actual dimensions or quantities of the components. Some of the details may not be fully sketched for the conciseness of the drawings.

What is claimed is:

1. A semiconductor device, comprising:
a semiconductor stack comprising a first semiconductor structure, a second semiconductor structure and an active region located between the first semiconductor structure and the second semiconductor structure;
a reflective structure located below the semiconductor stack, and comprising a first metal; and
a conductive structure located between the semiconductor stack and the reflective structure, and comprising a first region overlapping with the active region in a vertical direction and a second region which does not overlap with the active region in the vertical direction and comprises the first metal;
wherein the first metal in the second region has a concentration smaller than 5 atomic percent.

2. The semiconductor device according to claim 1, further comprising a barrier structure disposed between the reflective structure and the conductive structure.

3. The semiconductor device according to claim 2, wherein the barrier structure comprises a second metal different from the first metal.

4. The semiconductor device according to claim 2, wherein the barrier structure comprises a first side close to the reflective structure and a second side opposite to the first side, the first metal has a first concentration at the first side and a second concentration at the second side, and the first concentration is larger than the second concentration.

5. The semiconductor device according to claim 2, wherein the reflective structure has a first thickness, and the barrier structure has a second thickness smaller than the first thickness.

6. The semiconductor device according to claim 2, wherein the barrier structure comprising a first opening, and the first opening has a width smaller than that of the active region.

7. The semiconductor device according to claim 2, further comprising a base located at a side of the reflective structure away from the conductive structure, and a bonding structure located between the base and the reflective structure.

8. The semiconductor device according to claim 7, wherein the reflective structure has a width smaller than that of the base and larger than that of the active region.

9. The semiconductor device according to claim 8, the bonding structure directly contacting the barrier structure and the reflective structure.

10. The semiconductor device according to claim 1, further comprising an insulating structure located between the first semiconductor structure and the conductive structure.

11. The semiconductor device according to claim 1, further comprising a third semiconductor structure located between the first semiconductor structure and the conductive structure, the third semiconductor structure comprising a protruding portion extending towards the conductive structure.

12. The semiconductor device according to claim 11, wherein the third semiconductor structure comprising a first layer and a second layer.

13. The semiconductor device according to claim 11, further comprising an insulating structure located between the third semiconductor structure and the conductive structure, the insulating structure comprising a second opening corresponding to the protruding portion.

14. The semiconductor device according to claim 1, wherein the first metal comprises silver (Ag), aluminum (Al), copper (Cu), tin (Sn) or indium (In).

15. A semiconductor device, comprising:
a semiconductor stack comprising a first semiconductor structure, a second semiconductor structure and an active region located between the first semiconductor structure and the second semiconductor structure;
a reflective structure located below the semiconductor stack, and comprising a first metal;
a conductive structure located between the semiconductor stack and the reflective structure, and comprising a first region overlapping with the active region in a vertical direction and a second region which does not overlapped with the active region in the vertical direction; and
an insulating structure located between the semiconductor stack and the conductive structure, and comprising a third region and a fourth region respectively corresponding to the first region and the second region;
wherein the second region and the fourth region comprise the first metal, and the first metal in the fourth region has a concentration smaller than 5 atomic percent.

16. The semiconductor device according to claim 15, further comprising a barrier structure located between the conductive structure and the insulating structure.

17. The semiconductor device according to claim 16, wherein the barrier structure comprises a first side close to the reflective structure and a second side opposite to the first side, and the first metal has a first concentration at the first side and a second concentration at the second side, and the first concentration is larger than the second concentration.

18. The semiconductor device according to claim 16, wherein the barrier structure comprises a first opening, and the first opening has a width smaller than that of the active region.

19. The semiconductor device according to claim 18, further comprising a base located at a side of the reflective structure away from the conductive structure, wherein the reflective structure has a width smaller than that of the base and larger than that of the active region

20. A semiconductor package structure, comprising:
a package substrate;
a semiconductor device disposed on the package substrate, wherein the semiconductor device comprises:
a semiconductor stack comprising a first semiconductor structure, a second semiconductor structure and an active region located between the first semiconductor structure and the second semiconductor structure;
a reflective structure located below the semiconductor stack, and comprising a first metal; and
a conductive structure located between the semiconductor stack and the reflective structure, and comprising a first region overlapping with the active region in a vertical direction and a second region which does not overlap with the active region in the vertical direction and comprises the first metal;
wherein the first metal in the second region has a concentration smaller than 5 atomic percent; and
an encapsulating structure covering the semiconductor device.
